(19) United States
(12) Patent Application Publication
(10) Pub. No.: US 2006/0244069 A1
(43) Pub. Date: Nov. 2, 2006

(54) Semiconductor device having a gate dielectric of different blocking characteristics

(76) Inventors: Karsten Wieczorek, Dresden (DE); Michael Raab, Radebeul (DE); Karla Romero, Dresden (DE)

Correspondence Address: WILLIAMS, MORGAN & AMERSON, 10333 RICHMOND, SUITE 1100, HOUSTON, TX, 77042, US

(21) Appl. No.: 11/284,270

(22) Filed: Nov. 21, 2005

(30) Foreign Application Priority Data
Apr. 29, 2005 (DE) 10 2005 020 058.3

(51) Int. Cl. H01L 27/12

(52) U.S. Cl. 257/351

(57) ABSTRACT

By locally adapting the blocking capability of gate insulation layers for N-channel transistors and P-channel transistors, the reliability and threshold stability of the P-channel transistor may be enhanced, while nevertheless electron mobility of the N-channel transistor may be kept at a high level. This may be accomplished by incorporating a different amount of a dielectric dopant into respective gate insulation layer portions.

### BACKGROUND OF THE INVENTION

1. Field of the Invention

Generally, the present invention relates to the field of fabricating microstructures including integrated circuits, and, more particularly, to the formation of an ultra-thin dielectric layer, such as a gate dielectric layer for field effect transistors.

2. Description of the Related Art

Presently, microstructures are integrated into a wide variety of products. One example in this respect is the employment of integrated circuits that, due to their relatively low cost and high performance, are increasingly used in many types of devices, thereby allowing superior control and operation of those devices. Due to economic reasons, manufacturers of microstructures, such as integrated circuits, are confronted with the task of steadily improving performance of these microstructures with every new generation appearing on the market. However, these economic constraints not only require improving the device performance but also demand a reduction in size to provide more functionality of the integrated circuit per unit chip area. Thus, in the semiconductor industry, ongoing efforts are being made to reduce the feature sizes of feature elements.

In present-day technologies, the critical dimension of these elements approach 0.05 μm and even less. In producing circuit elements of this order of magnitude, along with many other issues especially arising from the reduction of feature sizes, process engineers are faced with the task of providing extremely thin dielectric layers on an underlying material layer, wherein certain characteristics of the dielectric layer, such as permittivity and/or resistance against charge carrier tunneling, blocking of impurities and the like, have to be improved, without sacrificing the physical properties of the underlying material layer.

One important example in this respect is the formation of ultra-thin gate insulation layers of field effect transistors, such as MOS transistors. The gate dielectric of a transistor has a significant impact on the performance of the transistor. As is commonly known, reducing the size of a field effect transistor, that is reducing the length of a conductive channel that forms in a portion of a semiconductor region by applying a control voltage to a gate electrode formed on a gate insulation layer, also requires the reduction of the thickness of the gate insulation layer to maintain the required capacitive coupling from the gate electrode to the channel region. Currently, most of the highly sophisticated integrated circuits, such as CPUs, memory chips and the like, are based on silicon, and therefore silicon dioxide has preferably been used as the material for the gate insulation layer due to the well-known and superior characteristics of the silicon dioxide/silicon interface. For a channel length on the order of 50 nm and less, however, the thickness of the gate insulation layer has to be reduced to about 1.5 nm or less in order to maintain the required controllability of the transistor operation. Steadily decreasing the thickness of the silicon dioxide gate insulation layer, however, leads to an increased leakage current therethrough, thereby resulting in an unacceptable increase of static power consumption as the leakage current exponentially increases for a linear reduction of the layer thickness.

Therefore, great efforts are presently being made to replace silicon dioxide by a dielectric exhibiting a significantly higher permittivity so that a thickness thereof may be remarkably higher than the thickness of a corresponding silicon dioxide layer providing the same capacitive coupling. A thickness for obtaining a specified capacitive coupling will also be referred to as capacitive equivalent thickness and determines the thickness that would be required for a silicon dioxide layer. It turns out, however, that it is difficult to incorporate high-k materials into the conventional integration process and, more importantly, the provision of a high-k material as a gate insulation layer seems to have a significant influence on the carrier mobility in the underlying channel region, thereby remarkably reducing the carrier mobility and thus the drive current capability. Hence, although an improvement of the static transistor characteristics may be obtained by providing a thick high-k material, at the same time an unacceptable degradation of the dynamic behavior presently makes this approach less than desirable.

A different approach that is currently favored is the employment of an integrated silicon oxide layer including a certain amount of nitrogen that may reduce the gate leakage current by 0.5 to 2 orders of magnitude while maintaining compatibility with standard CMOS process techniques. It has been found that the reduction of the gate leakage current mainly depends upon the nitrogen concentration incorporated into the silicon dioxide layer by means of plasma nitridation. Although this approach seems to relax the issue of gate dielectric leakage for the present circuit generation, this approach seems to be difficult for further aggressive dielectric thickness scaling required for device generations having a gate insulation layer thickness well below 2 nm, owing to reduced P-channel transistor reliability and/or reduced electron mobility in N-channel transistors.

As will be explained with reference to FIGS. 1a and 1b, the nitrogen within the silicon dioxide layer may also serve to reduce boron diffusion into the channel region of P-channel transistors due to the high diffusivity of boron, which may, once diffused into the channel region, cause a shift of the threshold voltage of the P-channel transistor, thereby compromising performance and reliability of the complete integrated circuit.

FIG. 1a schematically shows a cross-sectional view of a semiconductor device 100 comprising a substrate 101, such as a bulk silicon substrate or an SOI (silicon on insulator) substrate as may typically be used for the formation of complex integrated circuits, such as CPUs, storage chips, and the like. A first semiconductor region 102 and a second semiconductor region 103 are formed in or on the substrate 101 and may be separated by an isolation structure 104, which may be provided in the form of a trench isolation. Moreover, a gate insulation layer 105 is formed on the first and second semiconductor regions 102, 103 with a thickness in accordance with device requirements. The gate insulation layer 105 may be comprised of silicon dioxide with a thickness of 2 nm or even less for highly sophisticated integrated circuits.

The semiconductor device 100 as shown in FIG. 1a may be formed in accordance with the following processes. After the formation of the trench isolation 104 by well-established photolithography, trench etch, deposition and planarization techniques, a vertical dopant profile may be created within the first and second semiconductor regions 102, 103 as is required for advanced MOS transistor structures. For convenience, a corresponding vertical dopant profile is not shown in FIG. 1a. Thereafter, the gate insulation layer 105 may be formed by a well-established thermal oxidation process, which is controlled so as to substantially obtain the target thickness. Next, the semiconductor device 100 may be subjected to a nitridation process, indicated as 106, during which the surface of the gate insulation layer 105 is exposed to a nitrogen-containing plasma ambient to incorporate a certain amount of nitrogen into the silicon dioxide of the gate insulation layer 105. As previously discussed, an additional amount of nitrogen within the silicon dioxide may reduce charge carrier tunneling and may also influence the overall permittivity of the gate insulation layer 105. In addition, nitrogen within the gate insulation layer 105 may also affect the diffusion blocking capability of the gate insulation layer 105, in particular in view of boron diffusion, which may arise from a gate electrode structure to be formed on the gate insulation layer 105 in subsequent manufacturing steps and operation of the device. With the ever decreasing thickness of the gate insulation layer 105, for instance well below 2 nm, it is increasingly difficult to provide the required nitrogen concentration and to substantially confine the nitrogen to the gate insulation layer 105. Typically, a certain amount of nitrogen may also be incorporated into areas of the first and second semiconductor regions 102 and 103 that are located in the vicinity of an interface between the regions 102, 103 and the overlying gate insulation layer 105. However, nitrogen within the channel region of an N-channel transistor element may reduce the electron mobility and thus reduce the current drive capability of the transistor, thereby also compromising the overall performance of the semiconductor device 100. Consequently, the nitridation process 106 is controlled to obtain a trade-off between electron mobility degradation and boron diffusion blocking capability at the P-channel transistor. Thus, enhanced electron mobility and, therefore, transistor performance may be obtained at the cost of reduced P-channel reliability, and vice versa.

FIG. 1b schematically shows the semiconductor device 100 in a further advanced manufacturing stage. A first transistor 110 formed in and on the first semiconductor region 102 may represent a P-channel transistor, while a second transistor 120 formed in and on the second semiconductor region 103 may represent an N-channel transistor. During a boron implantation process, indicated as 131, the second transistor element 120 may be protected by a respective resist mask 130, while respective transistor regions, such as a gate electrode 111 and drain and source regions 112 of the first transistor 110, receive a boron concentration in accordance with device requirements. Corresponding regions, such as a gate electrode 121 and drain and source regions 122 of the second transistor 120, may previously have been implanted with an appropriate N-type dopant, which typically exhibits a significantly lower diffusivity compared to boron. During further manufacturing processes, such as any anneal steps to activate the implanted dopants, boron diffusion from the gate electrode 111 into the first semiconductor region 102 may be reduced to a degree as is given by the amount of nitrogen incorporated into the gate insulation layer 105 and into portions of the first and second semiconductor regions 102, 103. On the other hand, the increased nitrogen amount within the gate insulation layer 105 in the second transistor 120 may, during operation, compromise the transistor performance due to a reduced electron mobility. Consequently, with increasing nitrogen concentration within the gate insulation layer 105, performance of the second transistor 120 is increasingly reduced.

In view of the situation described above, a need exists for a technique that enables the formation of highly scaled transistor devices, thereby avoiding or at least reducing the effects of one or more problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique that enables the formation of gate insulation layers at different substrate locations, which exhibit different diffusion blocking capabilities, thereby allowing one to specifically design gate insulation layers for N-channel transistors and P-channel transistors in accordance with transistor-specific requirements.

According to one illustrative embodiment of the present invention, a method comprises forming a gate insulation layer on a first semiconductor region and a second semiconductor region. Moreover, the method comprises selectively adjusting a dopant blocking capability of the gate insulation layer to be different in a portion of the gate insulation layer corresponding to the first semiconductor region relative to a portion of the gate insulation layer corresponding to the second semiconductor region.

According to another illustrative embodiment of the present invention, a semiconductor device comprises a first transistor including a first gate electrode structure with a first gate insulation layer formed above a first semiconductor region. Moreover, the semiconductor device comprises a second transistor including a second gate electrode structure with a second gate insulation layer formed above a second semiconductor region, wherein the first gate insulation layer has a first dopant diffusion blocking capability that differs from a second dopant diffusion blocking capability of the second gate insulation layer.

### BRIEF DESCRIPTION OF THE DRAWINGS

The invention may be understood by reference to the following description taken in conjunction with the accompanying drawings, in which like reference numerals identify like elements, and in which:

FIGS. 1a-1b schematically illustrate cross-sectional views of a complementary transistor pair with an ultra-thin gate insulation layer during the manufacturing according to a conventional process technique; and

FIGS. 2a-2l schematically depict cross-sectional views of a complementary transistor pair with an ultra-thin gate insulation layer during various manufacturing stages according to illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention is based on the concept that the diffusion blocking capability of a gate insulation layer may be locally adjusted to correspond to desired transistor characteristics. For this purpose, dielectric dopants, which exhibit, in combination with a dielectric base material, a diffusion blocking effect, may be incorporated into a gate insulation layer in such a way that a specified first portion of the gate insulation layer receives the dielectric dopant material in a different concentration and/or receives a different species of dopant material compared to a second specified portion of the gate insulation layer.

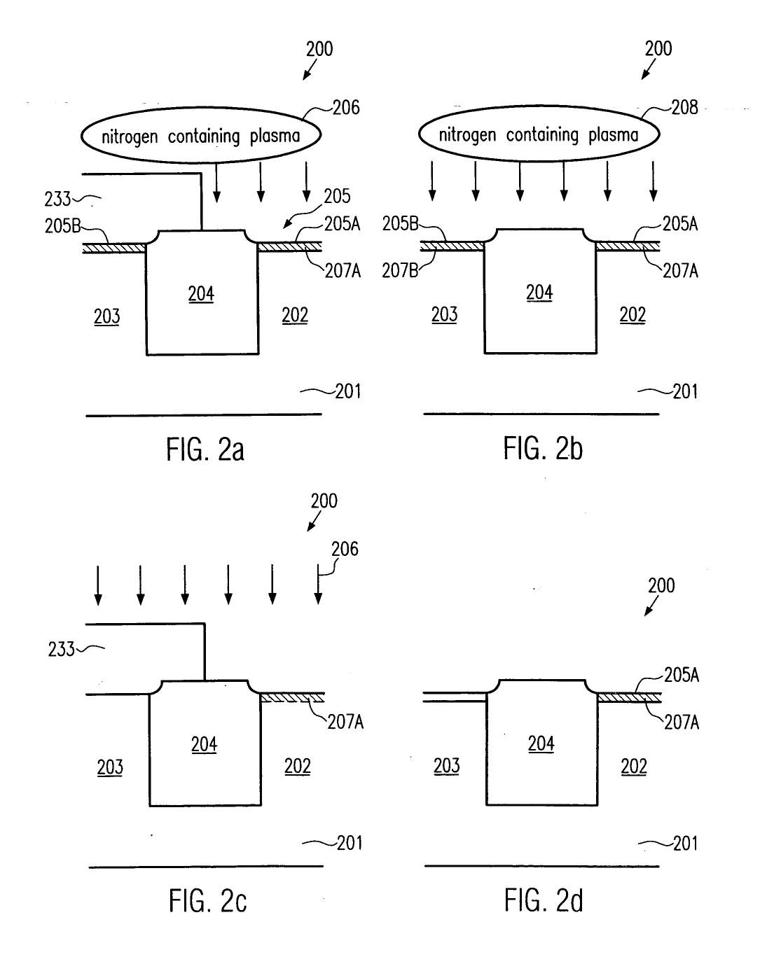

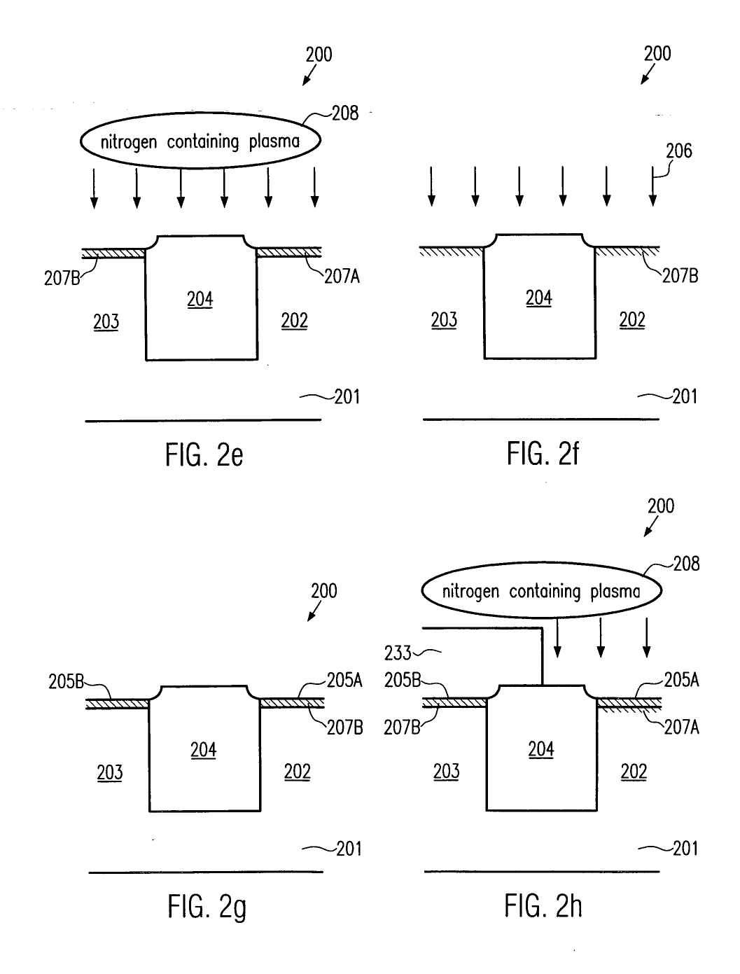

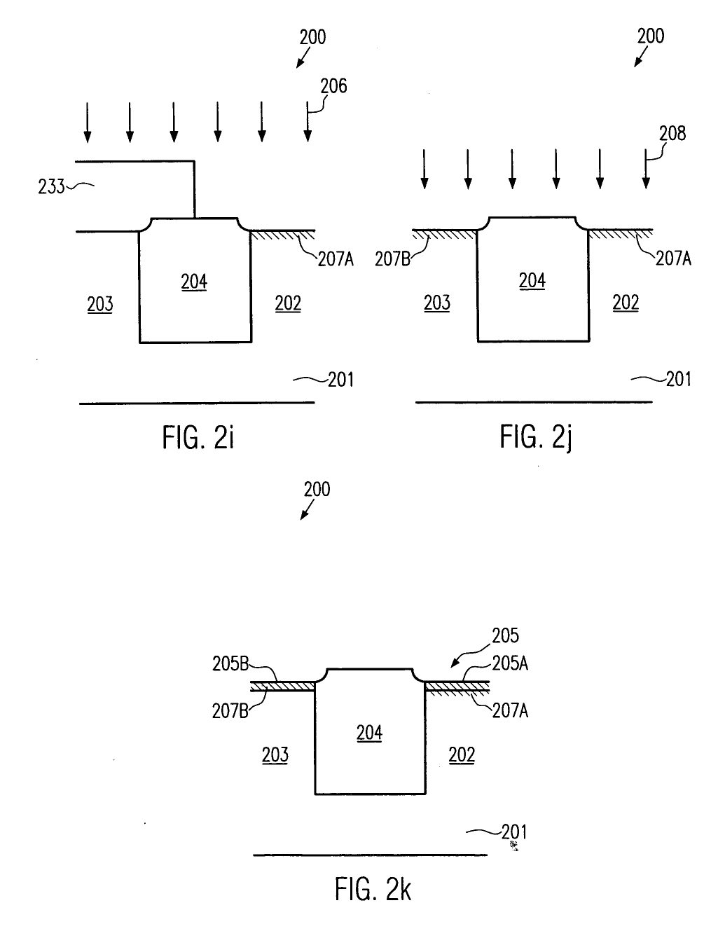

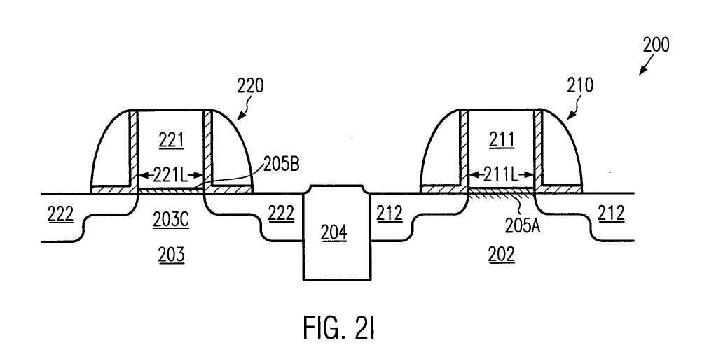

With reference to FIGS. 2a-2l, further illustrative embodiments of the present invention will now be described in more detail. FIG. 2a schematically shows a semiconductor device 200 comprising a substrate 201, which may represent a bulk silicon substrate, an SOI substrate and the like. The substrate 201 may have formed thereon a first semiconductor region 202 and a second semiconductor region 203, which may be comprised of any appropriate semiconductor material, such as silicon, silicon/germanium and the like. Moreover, the first and second semiconductor regions 202, 203 may differ in crystalline orientation and/or intrinsic strain that prevails in these regions or that may be established during the further manufacturing processes. The first and second semiconductor regions 202, 203 may be separated by an isolation structure 204, which may be provided in the form of a trench isolation as is presently preferably used in highly advanced semiconductor devices. The semiconductor device 200 further comprises a first portion 205a of a gate insulation layer 205, wherein the first portion 205a is formed on the first semiconductor region 202. Similarly, a second portion 205b of the gate insulation layer 205 is formed on the second semiconductor region 203. In one illustrative embodiment, the first and second portions 205a, 205b may initially be formed of an oxide of the underlying semiconductor material and thus may be formed in sophisticated CMOS devices in the form of silicon dioxide. In some embodiments, the semiconductor device 200 may include transistor elements having a gate length of approximately 50 nm or even less (see FIG. 2l). Consequently, a thickness of the gate insulation layer 205 may therefore be less than approximately 20 Å and may, in some particular embodiments, be approximately 12 Å and even less. Since silicon dioxide may not provide the required diffusion blocking characteristics, for instance in view of boron diffusion as is typically encountered in P-channel transistors, an appropriately high amount of a dielectric dopant species 207a is incorporated into the first portion 205a to obtain, in one illustrative embodiment, in combination with a subsequent dielectric dopant introduction into the portion 205b, a required final diffusion blocking behavior of the portion 205a, as will be described with reference to FIG. 2b.

A typical process flow for forming the semiconductor device 200 as shown in FIG. 2a may comprise the following processes. After the formation of the isolation structure 204 by well-established photolithography, trench etch, deposition and planarization techniques, advanced implantation sequences may be performed to produce the required dopant profile within the first and second semiconductor regions 202, 203. In one particular embodiment, the first semiconductor region 202 may be formed to enable the formation of a P-channel transistor, while the second semiconductor region 203 may receive an appropriate dopant profile to form therein and thereon an N-channel transistor. For this purpose, well-established implantation sequences with respective resist masks may be performed to obtain adequate dopant profiles within the regions 202 and 203. For convenience, any such dopant profiles are not shown. Thereafter, the gate insulation layer 205 may be formed, which may be achieved, in one illustrative embodiment, by a thermal oxidation process, wherein process parameters, such as oxidation time, composition of the oxidizing ambient and the like, are controlled to obtain a desired thickness of the layer 205, which may be, as previously stated, less than approximately 20 nm or even approximately 12 Å and even less. In other embodiments, the gate insulation layer 205 may be formed by advanced deposition techniques, such as chemical vapor deposition (CVD), atomic layer deposition (ALD) and the like. In yet other illustrative embodiments, the gate insulation layer 205 may be formed on the basis of a chemical oxidation using an appropriate chemistry to obtain a controlled growth of semiconductor oxide on the regions 202 and 203. It should be appreciated that the various techniques for forming the gate insulation 205 described above may be combined in any appropriate manner, depending on circumstances.

Thereafter, a mask 233 may be formed above the gate insulation layer 205 in such a way that at least the first portion 205a is exposed while the second portion 205b is covered. For instance, the mask 233 may be formed by substantially the same photolithography process as may also be used in creating different vertical dopant profiles within the regions 202 and 203. Based on the mask 233, the semiconductor device 200 may be subjected to a process 206 for incorporating the dielectric dopant species 207a into the first portion 205a. In one illustrative embodiment, the process 206 may represent a nitridation process, in which a plasma ambient is established that includes the species 207a. During the nitridation process, process parameters such as bias voltage applied between the plasma and the substrate 201, may be adjusted so as to substantially avoid undue penetration of the species 207a into the region 202. Moreover, the amount of the species 207a incorporated into the portion 205a may be adjusted in such a way that, in combination with a further dopant species to be incorporated into the portion 205b, the desired diffusion blocking capability in the portion 205a is achieved. In other embodiments, the nitridation process 206 may be controlled so as to incorporate an amount of the species 207a into the portion 205a as is appropriate for obtaining the specified diffusion blocking capability, when the incorporation of a further dopant species into the portion 205b is performed with the first portion 205a being covered by a respective mask (not shown).

In one particular embodiment, the species 207a may be comprised of nitrogen, as nitrogen, in combination with silicon dioxide, significantly reduces boron diffusion, charge carrier tunneling and the like. In some embodiments, when a modification of a thickness of the portion 205a is desired, the process 206 may, at least partially, be performed in an oxidizing ambient, thereby increasing the thickness of the portion 205a while also incorporating the species 207a. After the completion of the nitridation process 206, the mask 233 may be removed, for instance, by well-established resist ashing processes, where the mask 233 is provided as a resist mask, followed by well-established cleaning processes.

FIG. 2b schematically shows the semiconductor device 200 after the completion of the above-described processes. Moreover, the device 200 is subjected to a further process 208 for introducing a dielectric species 207b, which may, in some embodiments, be different from the species 207a, at least into the portion 205b. In the embodiment shown, the process 208 is performed simultaneously for both portions 205a, 205b, thereby increasing the concentration of the dielectric dopants within portion 205a, while obtaining a desired reduced dielectric dopant concentration within the portion 205b and thus within the neighboring semiconductor region 203. In one illustrative embodiment, the process 208 may be performed as a nitridation process, thereby also incorporating nitrogen as the species 207b. In other embodiments, the species 207b may represent another material, such as carbon and the like. Consequently, when the process 208 is performed without a mask for covering the portion 205a, the combined concentration of dielectric dopants, which is also denoted as 207a, received by the processes 206 and 208 in the layer portion 205a with a certain degree of penetration into the region 202, is selected to obtain the target concentration and thus the target diffusion blocking capability as is required for a highly advanced P-channel transistor to be formed in and on the region 202. At the same time, the dielectric dopant concentration in the portion 205b may be selected to obtain the required permittivity and blocking effect for electron tunneling, while maintaining the overall dielectric dopant concentration of the species 207b, for instance of nitrogen, within the region 203 at a required low level so as to not unduly compromise the electron mobility.

After the completion of the above-described sequence, a heat treatment may be performed to more uniformly distribute the species 207a and 207b within the respective portions 205b and 205a. For instance, a rapid thermal anneal process with a temperature in the range of approximately 600-1000° C. for a time period of 5-60 seconds may be appropriate to enhance the dielectric dopant uniformity within the portions 205a and 205b.

In still other illustrative embodiments, the sequence represented by FIGS. 2a and 2b may readily be inverted, that is, the process 208 may be applied on the initially formed gate insulation layer 205b, for instance without any mask, thereby substantially providing an identical dielectric dopant distribution within the portions 205a and 205b. Thereafter, the mask 233 may be formed and the process 206 may be carried out, thereby increasing the dielectric dopant concentration within the portion 205a to a desired level. After removal of the mask 233, a corresponding heat treatment may then be performed to enhance the dielectric dopant uniformity within the portions 205a and 205b.

FIG. 2c schematically shows the semiconductor device 200 in accordance with a further illustrative embodiment. In this case, the mask 233 is formed above the semiconductor region 203, possibly with any intermediate screening layers (not shown) and the like, while exposing the region 202, which may be covered by any screening layers and the like, which are, for convenience, not shown in FIG. 2c. Hence, the gate insulation layer 205 as shown in FIGS. 2a and 2b has not yet been formed. The semiconductor device 200 is subjected to the process 206 for incorporating dielectric dopants into the exposed region 202, wherein the process 206 may, for instance, represent an ion implantation process on the basis of nitrogen ions. Thus, the device 200 comprises the species 207a at a surface portion of the semiconductor region 202, wherein an average penetration depth of the species 207a may be controlled by the process parameters of the process 206. For instance, if the process 206 represents an ion implantation process, the implantation energy may correspondingly be selected to obtain a desired penetration depth. For example, for an average penetration depth on the order of magnitude of a thickness of the gate insulation layer 205 still to be formed, an implantation energy of several kV may be used. Hereby the presence of any screen layers, such as oxide layers and the like, may be taken into consideration when selecting an appropriate implantation energy. Suitable simulation programs for estimating the penetration depth of various ions into a variety of materials are available and may be used for selecting appropriate process parameters. After the process 206, the mask 233 may be removed and the semiconductor device 200 may be subjected to an oxidation process to form a gate insulation layer on the semiconductor regions 202 and 203.

FIG. 2d schematically shows the device 200 with the gate insulation layer 205 having the portions 205a and 205b, wherein additionally the portion 205a comprises the dielectric dopant species 207a. In one embodiment, the layer portions 205a, 205b may be formed by a thermal oxidation process, during which the diffusion of the dielectric dopant species 207a, for instance comprising nitrogen, is significantly reduced compared to the diffusion of oxygen and silicon, thereby ensuring that the dielectric dopant species 207a is substantially confined to the layer portion 205a, in particular when the average penetration depth during the process 206 substantially corresponds to the thickness of the layer 205.

FIG. 2e schematically shows the semiconductor device 200 during the process 208 for introducing a second dielectric dopant species 207b at least into the portion 205b. In the embodiment illustrated, the species 207b is also introduced into the layer portion 205a, thereby obtaining a final desired dielectric dopant concentration in and near the layer portion 205a. The process 208 may be performed as a nitridation process as previously described with reference to FIGS. 2a and 2b. It should further be appreciated, that the process 208 may also be performed by means of a mask to substantially avoid dielectric dopant incorporation in the layer portion 205a. In this case, the required dielectric dopant concentration of the species 207a may be adjusted entirely by the process 206, thereby providing an enhanced flexibility in independently adjusting the characteristics of the portions 205b and 205a, as is also described with reference to FIGS. 2a and 2b. Moreover, the process sequence described with reference to FIGS. 2a and 2b may also be performed on the basis of two masking steps so as to individually incorporate the species 207a and 207b with the respective other layer portion covered.

FIG. 2f schematically shows the semiconductor device 200 in accordance with a further illustrative embodiment. In this embodiment, the semiconductor device 200 is subjected to the process 206 for incorporating the dielectric dopant species, for instance the species 207b, which may comprise nitrogen, into the regions 202 and 203 without any mask. It should be appreciated that, although the gate insulation layer 205 is not yet formed, any other sacrificial layer, such as a screening layer, may be formed on the regions 202 and 203. For convenience, any such optional sacrificial layer is not shown in FIG. 2f. The process 206 may be performed as an ion implantation process, wherein process parameters, such as implantation energy and dose, may be appropriately selected, as is also discussed above.

FIG. 2g schematically shows the device 200 with the portions 205a and 205b of the gate insulation layer 205 formed above the regions 202 and 203, respectively. The gate insulation layer 205 may be formed by a thermal oxidation and/or a chemical oxidation, wherein the reduced diffusivity of the species 207b ensures the confinement of the dielectric dopants within and close to the portions 205a and 205b, as is also described with reference to FIG. 2b.

FIG. 2h schematically shows the device 200 after the formation of the mask 233 covering the portion 205b, while exposing the portion 205a. Moreover, the device 200 is subjected to the process 208 for incorporating the species 207a, thereby increasing the overall dielectric dopant concentration in the portion 205a and in the vicinity thereof. The process 208 may be a nitridation process as is previously described, or may be an ion implantation with appropriate process parameters.

FIG. 2i schematically shows the semiconductor device 200 in accordance with still another illustrative embodiment. In this case, the mask 233 is formed to cover the region 203 while exposing the region 202, wherein the gate insulation layer 205 is still to be formed. Moreover, with respect to any sacrificial layers formed on the regions 203 and 202, the same criteria apply as previously explained. Furthermore, the device 200 is subjected to the process 206 for incorporating the dielectric dopant species 207a into the region 202. For example, the process 206 may be an ion implantation on the basis of nitrogen ions, wherein appropriate process parameters may be used to control the average penetration depth in accordance with a targeted thickness of the gate insulation layer 205 to be formed.

FIG. 2j schematically shows the device 200 after removal of the mask 233 while being subjected to the process 208 for incorporating the second species 207b. Similarly, as previously discussed, the process 208 may also be performed on the basis of a mask (not shown) to substantially avoid the incorporation of the species 207b into the region 202, thereby requiring that the finally intended dielectric dopant concentration in the region 202 is achieved by the process 206. In the embodiment shown, the combined incorporation during the processes 206 and 208 provides the desired overall dielectric dopant concentration within the region 202 so that no further mask is required during the process 208. The process 208 may represent an ion implantation on the basis of, for instance, nitrogen ions, for which appropriate implantation parameters, such as energy and dose, may be selected so as to substantially achieve the target concentration within the regions 202 and 203. Corresponding process parameters may readily be obtained from simulation and/or experiment on the basis of test substrates. After the process 208, an optional heat treatment may be performed to enhance the uniformity of the species 207a and 207b in the depth direction and cure implantation-induced damage, wherein, for instance, a temperature in the range of approximately 700-1000° C. for a time period of 15-60 seconds may be appropriate, when nitrogen is used for the first and the second species 207a, 207b. In other embodiments, the gate insulation layer 205 may be formed by a thermal oxidation process without a preceding heat treatment, wherein, during an initial phase of the oxidizing process, the application of oxygen may be reduced or prevented to enhance the dielectric dopant uniformity prior to the actual oxidation. Consequently, implantation-induced damage in the regions 202 and 203 may substantially be re-crystallized while simultaneously the dielectric dopant uniformity is enhanced. In still other embodiments, however, the controlled thermal oxidation process may be performed upon the device 200 as shown in FIG. 2j without any preceding heat treatment or non-oxidizing periods.

FIG. 2k schematically shows the semiconductor device 200 after the formation of the gate insulation layer 205 including the portions 205a formed on the region 202 and the portion 205b formed on the region 203 having a different concentration of the dielectric dopant species 207a or 207b, when the same dopant species is used in the processes 206 and 208 and/or may have different types of dielectric dopant species, when different dopant species are used in the processes 206 and 208. Moreover, as described with respect to FIG. 2j, in particular embodiments, the gate insulation layer 205 may be formed by a thermal oxidation process, thereby allowing the employment of well-approved controlled thermal oxidation recipes. In other embodiments, after the process 208, the heat treatment, such as a rapid thermal anneal process, may be performed followed by a chemical oxidation process to form the portions 205a and 205b.

As described with reference to FIGS. 2a-2k, the embodiments of the present invention enable the formation of the gate insulation layer portions 205a, 205b having a locally adjusted and different diffusion blocking capability due to a different concentration of a diffusion blocking dielectric dopant and/or due to different types of dielectric dopants incorporated in the regions 205a and 205b. In particular embodiments, the dielectric dopant species used for adjusting the blocking capabilities of the layer portions 205a and 205b comprises nitrogen, which may be incorporated into the respective portions by a nitridation process and/or an ion implantation process, wherein typically a masking step may be used to provide a locally varying nitrogen concentration. Hence, an increased nitrogen concentration may be provided within the portion 205a and in the vicinity of the portion 205a to enhance the blocking effect in view of boron diffusion, thereby rendering the region 202 with the gate insulation layer portion 205a highly advantageous for the formation of P-channel transistors, while the characteristics of the portion 205b may specifically be tailored in order to not unduly compromise the electron mobility in the region 203 that may conventionally be caused by an undue nitrogen concentration in the vicinity of the layer portion 205b. It should further be appreciated that the embodiments described above for forming the portions 205a and 205b may be highly advantageous for the formation of complementary transistor pairs to significantly enhance the overall performance of the device 200. In other embodiments, the portions 205a and 205b may represent non-neighboring areas of a specific die region, which may require gate insulation layers of different characteristics. Moreover, the above-described process sequences are not restricted to the formation of two different portions 205a, 205b, but may be repeated by introducing further masking steps to generate three or more layer portions having different blocking capabilities. For example, transistor elements requiring extremely fast switching times may need an even more reduced concentration of nitrogen within their gate insulation layer portions compared to the still reduced concentration in the portion 205b. In such a situation the corresponding semiconductor region may be masked during two preceding dielectric dopant introduction steps, as are shown for instance in FIGS. 2a-2j, while, in a final step, an appropriate dielectric dopant concentration may be introduced into these semiconductor regions. The preceding steps for introducing dielectric dopants into the portions 205b and 205a may then accordingly be redesigned so as take into consideration the third step of introducing dielectric dopants. For more than three different blocking capabilities, this procedure may be repeated in accordance with device requirements.

On the basis of the substrate 200 having the layer portions 205a and 205b with the different blocking capabilities, the further processing of the device 200 may be continued on the basis of conventional techniques. That is, transistor elements may be formed in and on the regions 202 and 203 having their specifically designed gate insulation layers 205a and 205b.

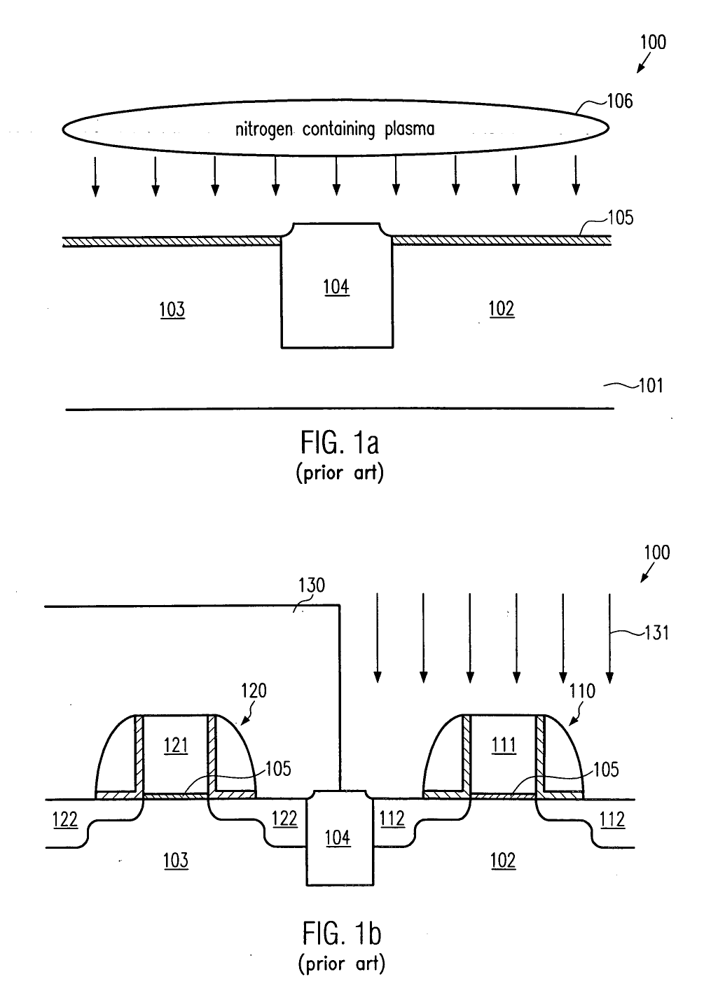

FIG. 2l schematically shows the device 200 in a further advanced manufacturing stage. A first transistor element 210 may be formed in and on the region 202 and may represent a P-channel transistor having P-doped, for instance boron-doped, drain/source regions 212 and a gate electrode structure 211 including the gate insulation layer 205a, wherein at least significant portions of the gate electrode structure may be doped with the same material as the drain/source regions 212, wherein undue dopant diffusion through the gate insulation layer 205a is suppressed. Similarly, the device 200 comprises a second transistor element 220, which may be an N-channel transistor having heavily N-doped source/drain regions 222 and a gate electrode structure 221, significant portions of which are also doped with an N-dopant. Due to the specifically designed gate insulation layer 205b of the gate electrode structure 221, the electron mobility within a channel region 203c is substantially not affected by the requirements with respect to the diffusion blocking capabilities of the gate insulation layer 205a, as is the case in the conventional transistor element 120 as shown in FIG. 1b. The transistors 210 and 220 may represent highly advanced transistor devices having a gate length 211l, 221l, respectively of approximately 50 nm and even less. However, it should be appreciated that the principles of the present invention may readily be applied to transistor elements having a longer gate length.

The transistor elements 210 and 220 may be formed in accordance with well-established processes including the deposition and patterning of the gate electrode structures 211 and 221 by well-established photolithography, etch and spacer formation techniques in combination with sophisticated implantation and anneal cycles. Moreover, other transistor architectures may be used, such as transistors having raised source/drain regions and/or transistor architectures requiring the formation of internal strain in the regions 202 and/or 203. Moreover, the regions 202 and 203 may represent semiconductor regions of the same material but differing crystalline orientations. It should further be appreciated that, although the device 200 is illustrated as a bulk device, a buried insulating layer may be formed within the regions 202 and 203 to provide substantially completed isolated transistor structures.

As a result, the present invention provides an enhanced technique for the formation of specifically designed gate insulation layers, in which particularly the blocking capabilities with respect to boron penetration of an underlying semiconductor region may individually be adapted to meet specific transistor requirements. Thus, the blocking capabilities of P-channel transistors may be enhanced by providing an increased concentration of, for instance, nitrogen in the respective gate insulation layer, while a performance degradation of the N-channel transistor may substantially be avoided in that a corresponding gate insulation layer is specifically designed for high electron mobility. Hence, the reliability and threshold stability of the P-channel transistor may be enhanced, while nevertheless electron mobility of the N-channel transistor may be kept at a high level.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a gate insulation layer on a first semiconductor region and a second semiconductor region; and
selectively adjusting a dopant blocking capability of said gate insulation layer so as to be different in a first portion of the gate insulation layer corresponding to said first semiconductor region relative to a second portion of said gate insulation layer corresponding to said second semiconductor region.

2. The method of claim 1, wherein selectively adjusting a blocking capability of said gate insulation layer comprises:
introducing a first concentration of a first species of a dielectric dopant into said first portion; and
introducing a second concentration of a second species of a dielectric dopant into said second portion, said first and second portions differing in at least one of concentration and species of dielectric dopants.

3. The method of claim 2, wherein said first species is selectively introduced into said first portion and said second species is commonly introduced into said first and second portions.

4. The method of claim 3, wherein selectively introducing said first species comprises forming a mask above said gate insulation layer, said mask exposing said first portion and covering said second portion.

5. The method of claim 4, wherein selectively introducing said first species comprises exposing said gate insulation layer to a plasma ambient containing said first species of dielectric dopants.

6. The method of claim 1, wherein a thickness of said gate insulation layer is approximately 20 Å or less.

7. The method of claim 2, wherein at least one of the first and second species of dielectric dopants is nitrogen.

8. The method of claim 2, wherein said first and second species comprise nitrogen.

9. The method of claim 3, wherein said first species is introduced prior to introducing said second species.

10. The method of claim 3, wherein said second species is introduced prior to introducing said first species.

11. The method of claim 1, wherein forming said gate insulation layer comprises oxidizing a surface portion of said first and second semiconductor regions.

12. The method of claim 3, further comprising performing a heat treatment after introducing said first and second species.

13. The method of claim 2, wherein said first species is introduced into at least said first semiconductor region prior to forming said gate insulation layer.

14. The method of claim 13, wherein said second species is introduced into said first and second portions after forming said gate insulation layer.

15. The method of claim 13, wherein said first species is introduced into said first and second semiconductor regions prior to forming said gate insulation layer.

16. The method of claim 15, wherein said second species is introduced into one of the first and second portions after forming said gate insulation layer.

17. The method of claim 2, wherein said first and second species are introduced into the first and second semiconductor regions prior to forming said gate insulation layer.

18. The method of claim 1, wherein forming said gate insulation layer comprises oxidizing a surface portion of said first and second semiconductor regions.

19. The method of claim 1, further comprising forming a first gate electrode structure of a first transistor above said first semiconductor region and forming a second gate electrode structure of a second transistor above said second semiconductor region.

20. The method of claim 19, wherein one of said first and second transistors represents a P-channel transistor and the other one represents an N-channel transistor.

21. A semiconductor device, comprising:
a first transistor including a first gate electrode structure with a first gate insulation layer formed above a first semiconductor region; and
a second transistor including a second gate electrode structure with a second gate insulation layer formed above a second semiconductor region,
said first gate insulation layer having a first dopant diffusion blocking capability that differs from a second dopant diffusion blocking capability of said second gate insulation layer.

22. The semiconductor device of claim 21, wherein said first and second transistors represent a complementary transistor pair.

23. The semiconductor device of claim 21, wherein said first and second gate insulation layers have a thickness of approximately 20 Å or less.

24. The semiconductor device of claim 23, wherein said first and second gate insulation layers have a thickness of approximately 12 Å or less.

25. The semiconductor device of claim 21, wherein said first and second gate insulation layers are comprised of silicon, oxygen and nitrogen.
